(19) United States
(12) Patent Application Publication
(10) Pub. No.: US 2011/0310552 A1
(43) Pub. Date: Dec. 22, 2011

(54) DUAL-PURPOSE EXTERNAL EXPANSION HARD DRIVE

(76) Inventor: Cheng Yu HUANG, Taipei (TW)

(21) Appl. No.: 12/820,377

(22) Filed: Jun. 22, 2010

(51) Int. Cl. H05K 5/03

(52) U.S. Cl. 361/679.37

(57) ABSTRACT

A dual-purpose external expansion hard drive provides functions of an external hard drive and a hot-plug hard drive. The external expansion hard drive has a hard-drive-carrying rotatory lid for slidingly receiving a hard drive and a socket case for accommodating the hard-drive-carrying rotatory lid. By closing or lifting the hard-drive-carrying rotatory lid rotatively, the external expansion hard drive is enabled to act as an external hard drive or a docking hard drive so that the external expansion hard drive provides dual-purpose functions.

### BACKGROUND OF THE INVENTION

1. Technical Field

The present invention relates to hard drives for computers, and more particularly, to a dual-purpose external expansion hard drive which provides functions of an external hard drive and a docking hard drive. The external expansion hard drive has a hard-drive-carrying rotatory lid for slidingly receiving a hard drive and a socket case for accommodating the hard-drive-carrying rotatory lid so as to allow the external expansion hard drive to act as an external hard drive, or for supporting the lifted hard-drive-carrying rotatory lid to allow the external expansion hard drive to act as a docking hard drive.

2. Description of Related Art

With the recent popularization of computer-related devices, the whole world has been involved in the rapidly developing torrent of information technology. As computers are in nature for information processing, users thereof invariably perform data store therewith and the stored data usually need to be carried to different places for later use. Therefore, there have been various storage media developed by the industry. Among others, hard disk drives which provide high efficiency and capacity are the most popular in the market.

Mobile hard disk drives, hereinafter as hard drives for short, are portable memory devices mainly classified as removable hard drives, external hard drives and docking hard drives. In a removable hard drive, the body of the hard drive and the connection device are undetachably integrated in respects of both operation and portability. The latter two otherwise have the hard drive independently operatable and portable. The common purpose of all these traditional approach is to provide users with conveniently mobile memories.

At present, the existing external hard drives (as the one shown in FIG. 1) and docking hard drives (as the one shown in FIG. 2) are extensively welcome among consumers due to their convenience. In normal use, an external hard drive or a docking hard drive is placed outside a personal computer or a server, and connected to the host through a signal cable or further connected to a source of direct current for being powered. Therefore, requirements related to such products are at least simple, easy use and operation.

However, the commercially available “external hard drive” for computers, in the course of installing or replacing the internal hard drive, requires double unscrewing and screwing operation. Particularly, for installing the hard drive, the hard drive has to be first screwingly fixed to a carrying board, and after the carrying board with the hard drive is placed in the device body, an outer cover has to be screwingly fixed to the device body. For uninstalling the hard drive, the above complicated operational procedures have to be performed in a reversed order. Obviously, the screw fixing process is complex and inconvenience. In addition, the appearance of the existing device is less sightly and is merely a closed storage device with its hard drive replaceable.

On the other hand, the existing “docking hard drive” is a storage tool having an opened structure and supports hot swapping, which allows a hard drive to be easily connected or disconnected. Each of the above-discussed two existing devices has its feature and merit. In short, in a case where the hard drive is seldom replaced, an “external hard drive” is relatively convenient. On the contrary, if the user needs to frequently make replacement among several hard drives, a “docking hard drive” would be a more reasonable choice.

Hence, it would be desired if the features and functions of two existing storage devices could be integrate into a single device. In view of this need, the inventor of the present invention who has invested time and energy, with his long-term rumination and years of experience in the art of computer peripherals, finally created the dual-purpose external expansion hard drive as disclosed herein.

### SUMMARY OF THE INVENTION

The present invention is thus provided to remedy the shortcomings of the traditional external hard drives and docking hard drives, and is configured to act as a stationary or a docking external expansion hard drive.

The present invention features a hard-drive-carrying rotatory lid and a socket case for accommodating or supporting the hard-drive-carrying rotatory lid. The hard-drive-carrying rotatory lid has a seat for slidingly receiving a hard drive. By closing the hard-drive-carrying rotatory lid, the external expansion hard drive is enabled to act as an external hard drive while by lifting the hard-drive-carrying rotatory lid rotatively, or the external expansion hard drive is enabled to act as a docking hard drive so that the external expansion hard drive provides dual-purpose functions.

### BRIEF DESCRIPTION OF THE DRAWINGS

The invention as well as a preferred mode of use, further objectives and advantages thereof will be best understood by reference to the following detailed description of illustrative embodiments when acquire in conjunction with the accompanying drawings, wherein:

FIG. 1 is a perspective view of a traditional external hard drive;

FIG. 2 is a perspective view of a traditional plug-in hard drive;

FIG. 3 is a perspective view of the present invention;

FIG. 4 is a left side view of the present invention;

FIG. 5 is a perspective view of the present invention from one view point showing a hard-drive-carrying rotatory lid lifted and a hard drive installed;

FIG. 6 is a perspective view of the present invention from another view point showing the hard-drive-carrying rotatory lid lifted and the hard drive installed;

FIG. 7 is an exploded view of the hard-drive-carrying rotatory lid of the present invention;

FIG. 8 is a perspective view of the present invention showing the hard-drive-carrying rotatory lid lifted without a hard drive installed;

FIG. 9 is a left side view of the present invention showing the hard-drive-carrying rotatory lid lifted without a hard drive installed;

FIG. 10 is a perspective view of the present invention showing the hard-drive-carrying rotatory lid lifted and supported by the socket case without a hard drive installed;

FIG. 11 is a left side view of the present invention showing the hard-drive-carrying rotatory lid lifted and supported by the socket case without a hard drive installed;

FIG. 12 is a perspective view of the present invention showing the hard-drive-carrying rotatory lid lifted and supported by the socket case with the hard drive received sliding into the hard-drive-carrying rotatory lid; and

FIG. 13 is a left side view of the present invention showing the hard-drive-carrying rotatory lid lifted and supported by the socket case with the hard drive received sliding into the hard-drive-carrying rotatory lid.

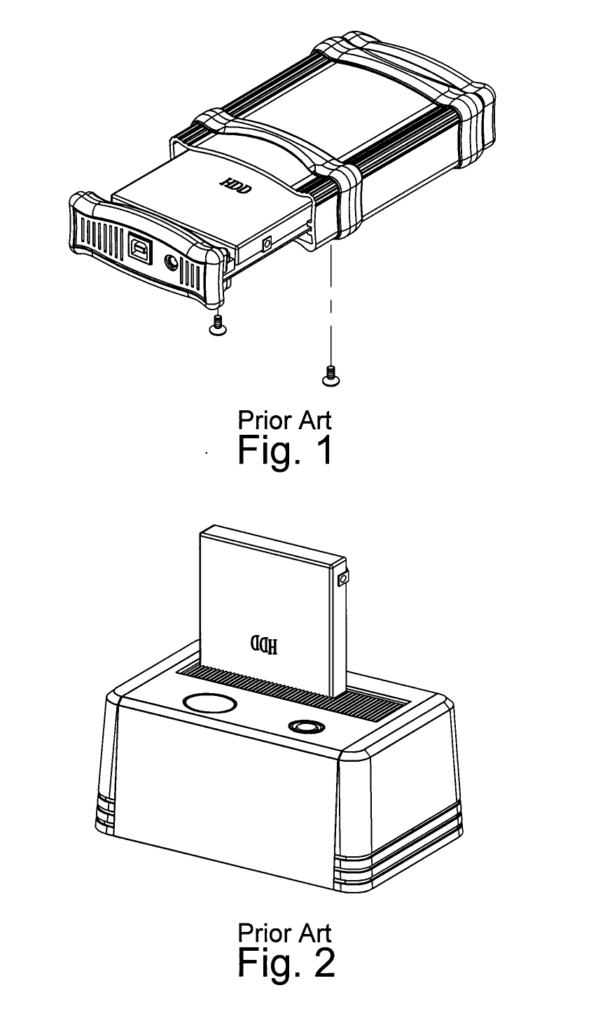

### DETAILED DESCRIPTION OF THE INVENTION

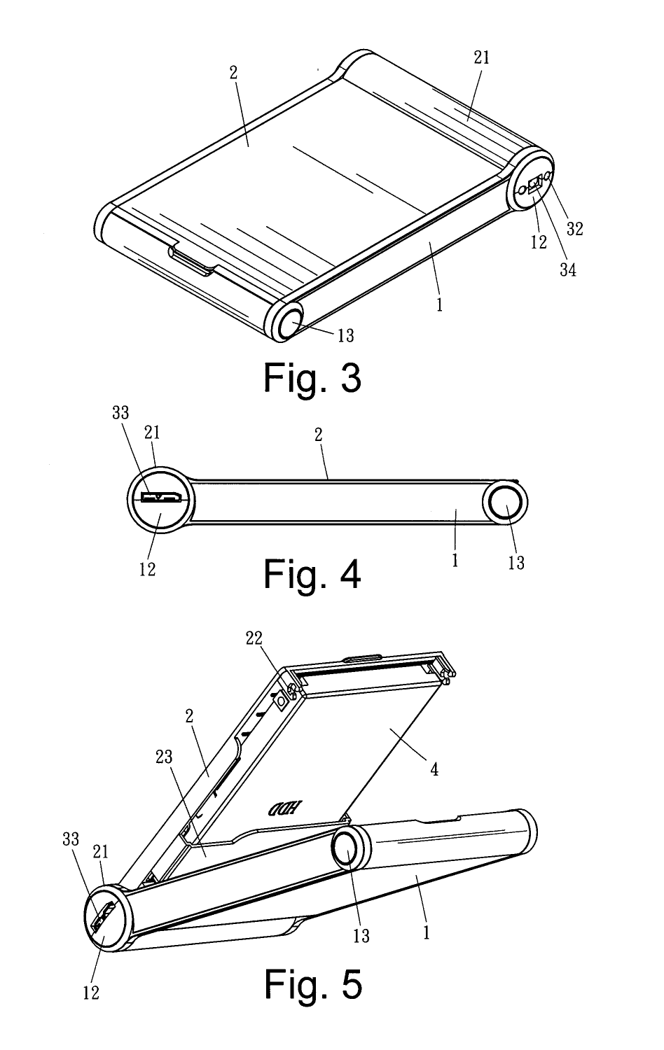

Referring to FIG. 3 through FIG. 6, according to the present invention, a dual-purpose external expansion hard drive primarily comprises a socket case 1 and a hard-drive-carrying rotatory lid 2.

The socket case 1 encloses an accommodating socket 11. The socket case 1 has a rear end bilaterally formed with a pair of symmetrical pivotal joints 12, and has a front end bilaterally formed with a pair of symmetrical resilient buttons 13. The resilient button 13 has its inner side provided with a retaining hook 14 while the accommodating socket 11 has a retaining surface 15 formed at an end thereof.

The hard-drive-carrying rotatory lid 2 has a rear end formed with a pivot 21 corresponding to the pivotal joints 12 of the socket case 1. The pivot 21 is pivotally fixed to the pivotal joints 12 so as to allow the hard-drive-carrying rotatory lid 2 to be lifted in a rotative manner and to be received in the accommodating socket 11 when closed. The hard-drive-carrying rotatory lid 2 has a front end formed with positioning notches 22 corresponding to the retaining hooks 14 in the resilient buttons 13 of the socket case 1.

Referring to FIG. 7, there is a circuit board 3 fixedly deposited in the pivot 21 of the hard-drive-carrying rotatory lid 2. The circuit board 3 has a hard-drive terminal 31 corresponding to a hard-drive seat 24 and an exposed process indicator LED light 32, as well as a USB terminal 33 for connection to computers, and a direct-current terminal 34.

A guiding plate 23 is provided on the hard-drive-carrying rotatory lid 2 so that the guiding plate 23 and the hard-drive-carrying rotatory lid 2 jointly define the hard-drive seat 24. The hard-drive seat 24 serves to slidingly receive a hard drive 4 so as to allow a terminal at the rear end of the hard drive 4 to connect the hard-drive terminal 31 of the circuit board 3.

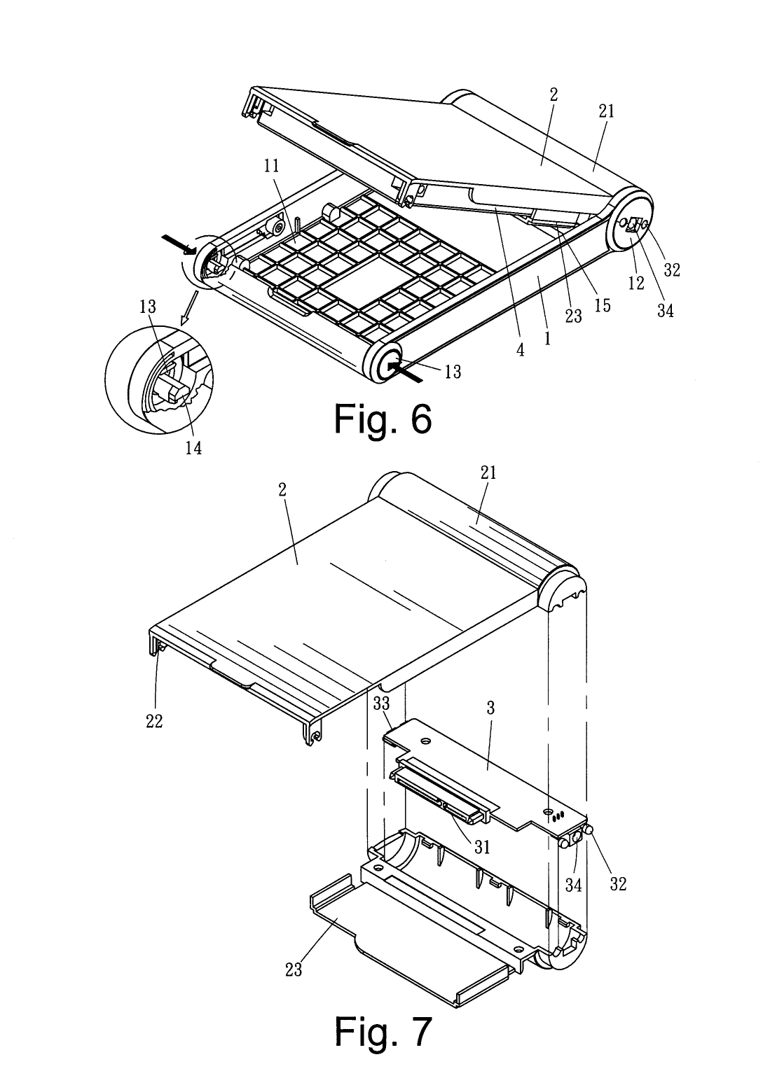

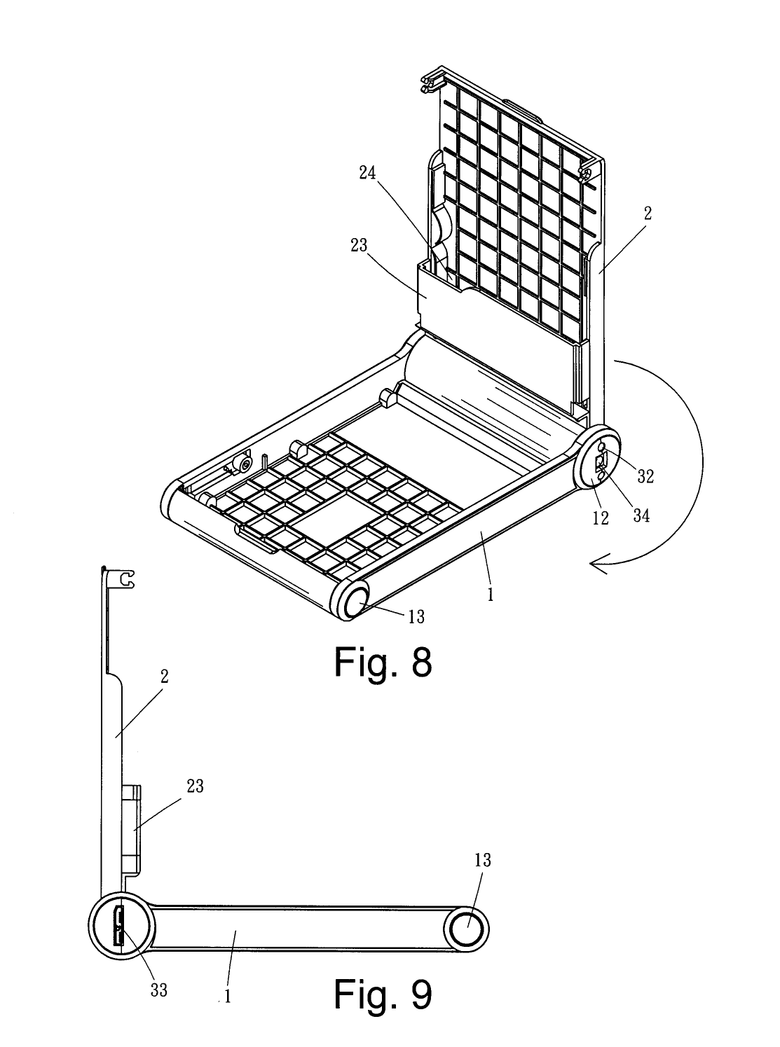

Referring to FIG. 8 and FIG. 9, in use, the resilient buttons 13 on the socket case 1 are pressed to disengage the retaining hooks 14 from the positioning notches 22 of the hard-drive-carrying rotatory lid 2. Returning to FIG. 5 and FIG. 6, the hard-drive-carrying rotatory lid 2 is therefore allowed to be lifted in a rotative manner in order to install or replace the hard drive 4, thus the disclosed device acting as a closed external hard drive.

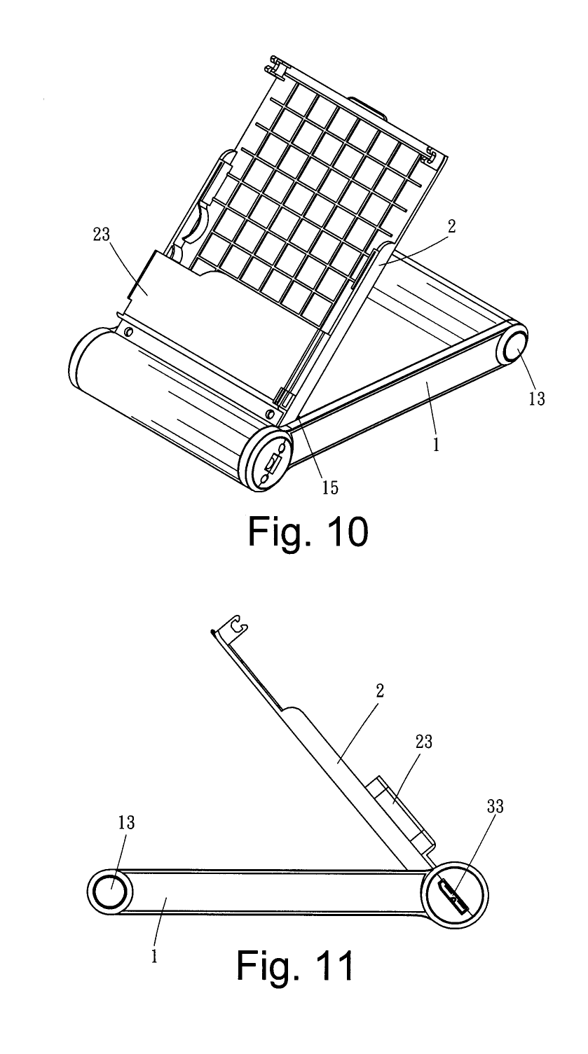

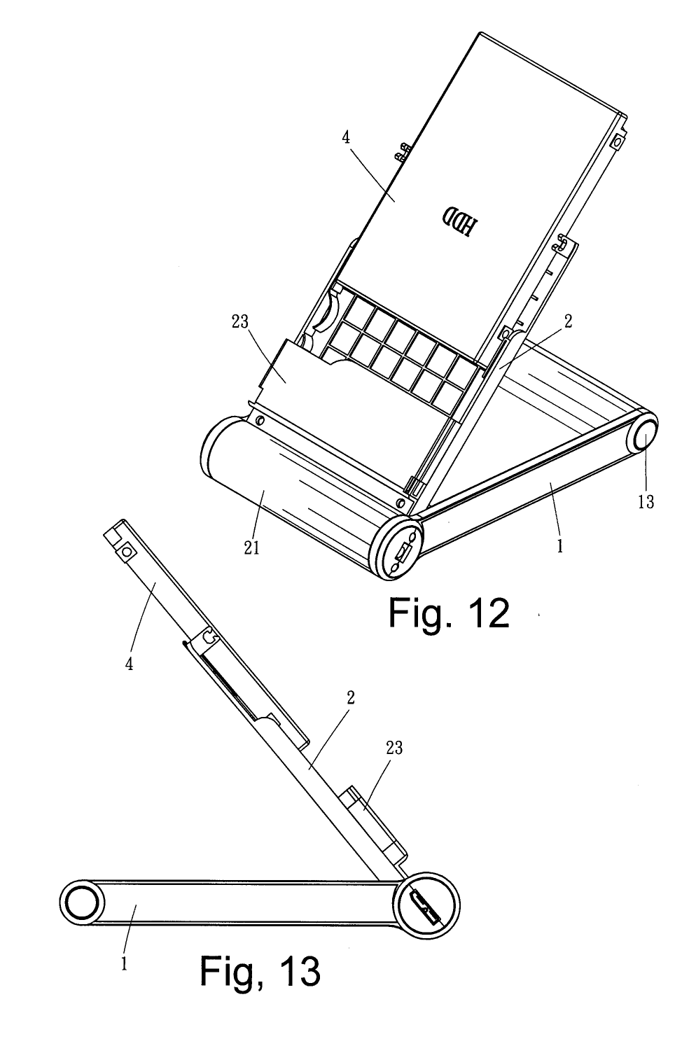

Referring to FIG. 10 through FIG. 13, in alternative use, the hard-drive-carrying rotatory lid 2 pivots further toward a back of the socket case 1 until gets positioned by the retaining surface 15, and the socket case 1 thus forms a support to allow the disclosed device to be operated as a hot-plug docking hard drive. Thereby, the disclosed external expansion hard drive independently provides dual-purpose functions.

What is claimed is:

1. A dual-purpose external expansion hard drive, comprising a socket case 1 and a hard-drive-carrying rotatory lid 2, the hard-drive-carrying rotatory lid 2 configured to receive a hard drive 4 being pivotally connected to the socket case 1 so that the hard-drive-carrying rotatory lid 2 is allowed to be received in the socket case 1 and act as a closed external hard drive, and so that the hard-drive-carrying rotatory lid 2 is allowed to be lifted in a rotative manner toward a back of the socket case 1 until positioned by a retaining surface 15 on the socket case so that the socket case 1 forms a support to allow the dual-purpose external expansion hard drive to be operated as a hot-plug docking hard drive, thereby the external expansion hard drive providing dual-purpose functions.

2. The dual-purpose external expansion hard drive of claim 1, wherein the socket case 1 encloses an accommodating socket 11 and has a rear end bilaterally formed with a pair of symmetrical pivotal joints 12 as well as a front end bilaterally formed with a pair of symmetrical resilient buttons 13, each said resilient button 13 having an inner side provided with a retaining hook 14 while the accommodating socket 11 has the retaining surface 15 formed at an end thereof.

3. The dual-purpose external expansion hard drive of claim 1, wherein the hard-drive-carrying rotatory lid 2 has a rear end formed with a pivot 21 corresponding to the pivotal joints 12 of the socket case 1, the pivot 21 being pivotally fixed to the pivotal joints 12 so as to allow the hard-drive-carrying rotatory lid 2 to be lifted in the rotative manner and to be received in the accommodating socket 11 when closed, and the hard-drive-carrying rotatory lid 2 having a front end formed with positioning notches 22 corresponding to the retaining hooks 14 in the resilient buttons 13 of the socket case 1.

4. The dual-purpose external expansion hard drive of claim 3, wherein a circuit board 3 is fixedly deposited in the pivot 21 of the hard-drive-carrying rotatory lid 2 and has a hard-drive terminal 31 corresponding to a hard-drive seat 24 on the hard-drive-carrying rotatory lid 2, an exposed process indicator LED light 32, a USB terminal 33 for connection to computers, and a direct-current terminal 34.

5. The dual-purpose external expansion hard drive of claim 3, wherein a guiding plate 23 is provided on the hard-drive-carrying rotatory lid 2 so that the guiding plate 23 and the hard-drive-carrying rotatory lid 2 jointly define a hard-drive seat 24 that serves to slidingly receive the hard drive 4 so as to allow a terminal at a rear end of the hard drive 4 to connect a hard-drive terminal 31 of the circuit board 3.
